(19) United States
(12) Patent Application Publication
(10) Pub. No.: US 2026/0085401 A1
(43) Pub. Date: Mar. 26, 2026

(54) SELECTIVE SURFACE PASSIVATION AND INITIATED POLYMERIZATION FOR AREA SELECTIVE DEPOSITION

(71) Applicant: International Business Machines Corporation, Armonk, NY (US)

(72) Inventors: Thomas Geoffrey Pattison, Moonee Ponds (AU); Ishwar Singh, Sunnyvale, CA (US); Noel Arellano, Gilroy, CA (US); Rudy J. Wojtecki, San Jose, CA (US)

(21) Appl. No.: 18/894,329

(22) Filed: Sep. 24, 2024

(51) Int. Cl. C23C 16/04; C23C 16/455; H01L 21/02

(52) U.S. Cl. CPC C23C 16/04; C23C 16/45525; H10P 14/6339; H10P 14/683

(57) ABSTRACT

A process of area selective deposition (ASD), a process of atomic layer deposition (ALD), and a process of device fabrication include forming a passivation layer on a metal surface of a substrate and forming a surface-bound polymer film on a dielectric surface of the substrate. The forming the passivation layer includes binding metal-selective inhibitor molecules to the metal surface. A device is formed in a process that includes forming a passivation layer on a metal surface of a substrate and forming a surface-bound polymer film on a dielectric surface of the substrate. The forming the passivation layer includes binding metal-selective inhibitor molecules to the metal surface. A composition for area selective deposition (ASD) includes a metal-selective inhibitor molecule have the following structure:

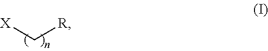

wherein X is a metal-binding group, R is an organic ligand, and n is an integer greater than or equal to zero.

### BACKGROUND

The present disclosure relates to area selective deposition and, more specifically, to compounds for selectively passivating surfaces of a substrate.

Area selective deposition (ASD) can be used to form patterned films without lithographic or subtractive processes. ASD can introduce surface topography to enable self-aligned processes for device fabrication. Examples of ASD techniques include atomic layer deposition (ALD), which can be used in the manufacture of semiconductor and microelectronic devices. ALD is a bottom-up process employing atomic layer-by-layer control of film compositions. This method of film generation can include chemical reactions at a surface wherein two self-limiting half reactions are alternated to produce conformal thin films on features and three-dimensional structures with a variety of materials. These reactions can be inhibited in a controllable manner to achieve selective deposition.

### SUMMARY

Various embodiments are directed to processes of area selective deposition (ASD), atomic layer deposition (ALD), and device fabrication that include forming a passivation layer on a metal surface of a substrate and forming a surface-bound polymer film on a dielectric surface of the substrate. The forming the passivation layer includes binding metal-selective inhibitor molecules to the metal surface.

Additional embodiments are directed to a device formed in a process that includes forming a passivation layer on a metal surface of a substrate and forming a surface-bound polymer film on a dielectric surface of the substrate. The forming the passivation layer includes binding metal-selective inhibitor molecules to the metal surface.

Further embodiments are directed to a composition for area selective deposition (ASD) that includes a metal-selective inhibitor molecule with the following structure:

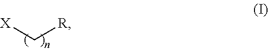

wherein X is a metal-binding group, R is an organic ligand, and n is an integer greater than or equal to zero.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 is a flow diagram illustrating a process of area selective deposition (ASD), according to some embodiments.

FIG. 2 is a schematic diagram illustrating a process of ASD on a substrate (side view), according to some embodiments.

FIG. 3A illustrates chemical structure diagrams of example metal-binding groups (X1-X4) for inhibitor molecules, according to some embodiments.

FIG. 3B illustrates chemical structure diagrams of example organic ligands (R1-R4) for inhibitor molecules, according to some embodiments.

FIG. 3C illustrates chemical structure diagrams of metal-selective inhibitor molecules (a-p), according to some embodiments.

FIG. 4 is a chemical reaction diagram illustrating a process of synthesizing a metal-selective inhibitor molecule, according to some embodiments.

While the invention is amenable to various modifications and alternative forms, specifics thereof have been shown by way of example in the drawings, and will be described in detail. It should be understood, however, that the intention is not to limit the invention to the particular embodiments described. Instead, the intention is to cover all modifications, equivalents, and alternatives falling within the spirit and scope of the invention.

### DETAILED DESCRIPTION

Embodiments of the present invention are generally directed to semiconductor device fabrication and, more specifically, to area selective deposition. While the present disclosure is not necessarily limited to such applications, various aspects of the disclosure may be appreciated through a discussion of examples using this context.

Although the present invention has been described in reference to specific embodiments, it should be understood that the invention is not limited to these examples only and that many variations of these embodiments may be readily envisioned by the skilled person after having read the present disclosure. The invention may thus further be described without limitation, and by way of example only, by the following embodiments.

Embodiment 1: A process of area selective deposition (ASD), comprising forming a passivation layer on a metal surface of a substrate, wherein the forming the passivation layer includes binding metal-selective inhibitor molecules to the metal surface, and forming a surface-bound polymer film on a dielectric surface of the substrate.

Technical advantages of embodiment 1 can include improving pattern resolution in the ASD by directing selective growth of polymer films.

Embodiment 2: The process of embodiment 1, further comprising performing atomic layer deposition (ALD) on the metal surface.

A technical effect of embodiment 2 can include forming a patterned film on metal features of the substrate.

Embodiment 3: The process of embodiment 2, further comprising removing the passivation layer from the metal surface prior to performing the ALD.

Technical advantages of embodiment 3 can include improving ALD resolution when the passivation layer is able to inhibit ALD.

Embodiment 4: The process of any of embodiments 1-3, wherein the metal-selective inhibitor molecules have the following structure:

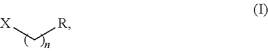

wherein X is a metal-binding group, R is an organic ligand, and n is an integer greater than or equal to zero.

The metal-selective inhibitor molecules of embodiment 4 may advantageously provide a driving force for the formation of a chemically and thermally stable monolayer for passivation of the metal surfaces. A technical effect of the metal-binding group X can be causing preferential binding to the metal surface of the substrate relative to the dielectric surface. Technical effects of R and n can include determining the packing efficiency the inhibitor molecules bound to the metal surface.

Embodiment 5: The process of embodiment 4, wherein X is selected from the group consisting of hydroxamic acid, phosphonic acid, thiol, and carboxylic acid.

Advantages of the species in embodiment 5 may include a preference for binding to a metal or metal oxide rather than a dielectric surface.

Embodiment 6: The process of embodiment 4 or 5, wherein n=3.

Technical effects of embodiment 6 may contribute to packing efficiency and stability of the passivation layer.

Embodiment 7: The process of any of embodiments 4-6, wherein R is selected from the group consisting of an alkyl chain, adamantyl, and phenyl.

Technical effects of the selection of R in embodiment 7 may contribute to packing efficiency and stability of the passivation layer.

Embodiment 8: The process of any of embodiments 1-7, further comprising treating the substrate with oxygen plasma prior to the passivating.

Technical effects of embodiment 8 can include oxidizing the metal surface and cleaning the substrate.

Embodiment 9: The process of any of embodiments 1-8, wherein the forming the surface-bound polymer film comprises functionalizing the dielectric surface with surface-bound initiator molecules.

Technical effects of embodiment 9 can include tethering the polymer film to the dielectric surface.

Embodiment 10: A process of atomic layer deposition (ALD), comprising forming a passivation layer on a metal surface of a substrate, wherein the forming the passivation layer includes binding metal-selective inhibitor molecules to the metal surface, and forming a surface-bound polymer film on a dielectric surface of the substrate.

Technical advantages of embodiment 10 can include improving pattern resolution in ASD by directing selective growth of polymer films.

Embodiment 11: The process of embodiment 10, wherein the metal-selective inhibitor molecules have the following structure:

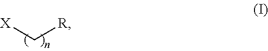

wherein X is a metal-binding group, R is an organic ligand, and n is an integer greater than or equal to zero.

The metal-selective inhibitor molecules of embodiment 11 may advantageously provide a driving force for the formation of a chemically and thermally stable monolayer for passivation of the metal surfaces. A technical effect of the metal-binding group X can be causing preferential binding to the metal surface of the substrate relative to the dielectric surface. Technical effects of R and n can include determining the packing efficiency the inhibitor molecules bound to the metal surface.

Embodiment 12: The process of embodiment 11, wherein X is selected from the group consisting of hydroxamic acid, phosphonic acid, thiol, and carboxylic acid.

Advantages of the species in embodiment 12 may include a preference for binding to a metal or metal oxide rather than a dielectric surface.

Embodiment 13: The process of embodiments 11 or 12, wherein n=3.

Technical effects of embodiment 13 may contribute to packing efficiency and stability of the passivation layer.

Embodiment 14: The process of any of embodiments 11-13, wherein R is selected from the group consisting of an alkyl chain, adamantyl, and phenyl.

Technical effects of the selection of R in embodiment 14 may contribute to packing efficiency and stability of the passivation layer.

Embodiment 15: The process of any of embodiments 10-14, wherein the forming the surface-bound polymer film comprises functionalizing the dielectric surface with surface-bound initiator molecules.

Technical effects of embodiment 15 can include tethering the polymer film to the dielectric surface.

Embodiment 16: A process of device fabrication, comprising forming a passivation layer on a metal surface of a substrate, wherein the forming the passivation layer includes binding metal-selective inhibitor molecules to the metal surface, and forming a surface-bound polymer film on a dielectric surface of the substrate.

Technical advantages of embodiment 16 can include improving pattern resolution by preventing growth of polymer films that inhibit ALD on metal surfaces.

Embodiment 17: The process of embodiment 16, wherein the metal-selective inhibitor molecules have the following structure:

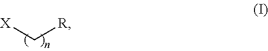

wherein X is a metal-binding group, R is an organic ligand, and n is an integer greater than or equal to zero.

The metal-selective inhibitor molecules of embodiment 17 may advantageously provide a driving force for the formation of a chemically and thermally stable monolayer for passivation of the metal surfaces. A technical effect of the metal-binding group X can be to cause preferential binding to the metal surface of the substrate relative to the dielectric surface. Technical effects of R and n can include determining the packing efficiency the inhibitor molecules bound to the metal surface.

Embodiment 18: The process of embodiment 16 or 17, wherein the forming the surface-bound polymer film comprises functionalizing the dielectric surface with surface-bound initiator molecules.

Technical effects of embodiment 18 can include tethering the polymer film to the dielectric surface.

Embodiment 19: The process of any of embodiments 16-18, further comprising removing the passivation layer and forming a metal oxide film on the metal surface without the passivation layer.

Technical advantages of embodiment 19 can include improving pattern resolution of the metal oxide film when the passivation layer is able to inhibit the ALD.

Embodiment 20: A device formed in a process comprising forming a passivation layer on a metal surface of a substrate, wherein the forming the passivation layer includes binding metal-selective inhibitor molecules to the metal surface, and forming a surface-bound polymer film on a dielectric surface of the substrate.

The device of embodiment 20 can be advantageously smaller than conventionally formed devices due to improved pattern resolution when performing atomic layer deposition (ALD) on metal features of the device.

Embodiment 21: The process of embodiment 20, wherein the metal-selective inhibitor molecules have the following structure:

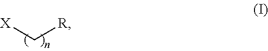

wherein X is a metal-binding group, R is an organic ligand, and n is an integer greater than or equal to zero.

The metal-selective inhibitor molecules of embodiment 21 may advantageously provide a driving force for the formation of a chemically and thermally stable monolayer for passivation of the metal surfaces. A technical effect of the metal-binding group X can be to cause preferential binding to the metal surface of the substrate relative to the dielectric surface. Technical effects of R and n can include determining the packing efficiency the inhibitor molecules bound to the metal surface.

Embodiment 22: The process of embodiment 21, wherein X is selected from the group consisting of hydroxamic acid, phosphonic acid, thiol, and carboxylic acid.

Embodiment 23: The process of 21 or 22, wherein R is selected from the group consisting of an alkyl chain, adamantyl, and phenyl.

Embodiment 24: The device of any of embodiments 20-23, the forming the surface-bound polymer film comprises functionalizing the dielectric surface with surface-bound initiator molecules.

Technical effects of embodiment 24 can include tethering the polymer film to the dielectric surface.

Embodiment 25: A composition for area selective deposition (ASD) comprising a metal-selective inhibitor molecule have the following structure:

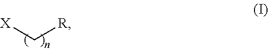

wherein X is a metal-binding group, R is an organic ligand, and n is an integer greater than or equal to zero.

The metal-selective inhibitor molecule of embodiment 25 may advantageously provide a driving force for the formation of a chemically and thermally stable monolayer for passivation of metal surfaces. A technical effect of the metal-binding group X can be to cause preferential binding to the metal surface of the substrate relative to the dielectric surface. Technical effects of R and n can include determining the packing efficiency the inhibitor molecules bound to the metal surface.

Various embodiments of the present disclosure are described herein with reference to the related drawings, where like numbers refer to the same component. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “over,” “positioned on,” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

As used herein, the articles “a” and “an” preceding an element or component are intended to be nonrestrictive regarding the number of instances (i.e., occurrences) of the element or component. Therefore, “a” or “an” should be read to include one or at least one, and the singular word form of the element or component also includes the plural unless the number is obviously meant to be singular.

As used herein, the terms “invention” or “present invention” are non-limiting terms and not intended to refer to any single aspect of the particular invention but encompass all possible aspects as described in the specification and the claims.

Unless otherwise noted, ranges (e.g., time, concentration, temperature, etc.) indicated herein include both endpoints and all numbers between the endpoints. Unless specified otherwise, the use of a tilde (˜) or terms such as “about,” “substantially,” “approximately,” “slightly less than,” and variations thereof are intended to include the degree of error associated with measurement of the particular quantity based upon the equipment available at the time of filing the application. For example, “about” can include a range of +8% or 5%, or 2% of a given value, range of values, or endpoints of one or more ranges of values. Unless otherwise indicated, the use of terms such as these in connection with a range applies to both ends of the range (e.g., “approximately 1 mL-5 L” should be interpreted as “approximately 1 milliliter to approximately 5 liters”) and, in connection with a list of ranges, applies to each range in the list (e.g., “about 1-5 g, 5-10 g, etc.” should be interpreted as “about 1 gram to about 5 grams, about 5 grams to about 10 grams, etc.”).

As described herein, compounds of the present disclosure can optionally be substituted with one or more substituents, as exemplified by particular classes, subclasses, and species of the present disclosure. As described herein, any of the above moieties or those introduced below can be optionally substituted with one or more substituents described herein. However, it is generally known that the substituents should be selected so that they do not adversely affect the useful properties of the compound or its function. The term “substituted” in the context of the present disclosure means that one or more hydrogen atoms of the indicated radical or group is/are independently replaced by the same or a different substituent(s). Additionally, the term “substituted” specifically provides for one or more, e.g., two, three, or more, substituents commonly used in the art.

As used herein the term “aliphatic” encompasses the terms alkyl, alkenyl, or alkynyl. Aliphatic radicals or groups may have any degree of saturation, such as groups having only single carbon-carbon bonds (“alkyl” or “alkylene”), groups having one or more double carbon-carbon bonds (“alkenyl”), radicals having one or more triple carbon-carbon bonds (“alkynyl”), and groups having a mixture of single, double and/or triple carbon-carbon bonds.

As used herein, an “alkyl” group refers to a saturated aliphatic hydrocarbon group containing at least one carbon atom (e.g., C1-C4, C1-C6, or C1-C8 alkyls). An alkyl group can be straight, branched, cyclic, or any combination thereof. Unless specifically limited otherwise, the term “alkyl,” as well as derivative terms such as “alkoxy” and “thioalkyl,” as used herein, include within their scope, straight chain, branched chain, and cyclic moieties. If the alkyl radical is further bonded to another atom, it becomes an alkylene radical or alkylene group. In other words, the term “alkylene” also refers to a divalent linear or branched alkyl. For example, —CH₂CH₃ is an ethyl, while —CH₂CH₂— is an ethylene. The term “alkylene” alone or as part of another substituent refers to a saturated linear or branched divalent hydrocarbon radical obtained by removing two hydrogen atoms from a single carbon atom or two different carbon atoms of a starting alkane.

Examples of alkyl radicals/moieties or alkyl groups include methyl, ethyl, propyl, 1-methylethyl, butyl, 1-methylpropyl, 2-methylpropyl, 1,1-dimethylethyl, pentyl, 1-methylbutyl, 2-methylbutyl, 3-methylbutyl, 2,2-dimethylpropyl, 1-ethylpropyl, hexyl, 1,1-dimethylpropyl, 1,2-dimethylpropyl, 1-methylpentyl, 2-methylpentyl, 3-methylpentyl, 4-methylpentyl, 1,1-dimethylbutyl, 1,2-dimethylbutyl, 1,3-dimethylbutyl, 2,2-dimethylbutyl, 2,3-dimethylbutyl, 3,3-dimethylbutyl, 1-ethylbutyl, 2-ethylbutyl, 1,1,2-trimethylpropyl, 1,2,2-trimethylpropyl, 1-ethyl-1-methylpropyl, and 1-ethyl-2-methylpropyl. The alkyl group or alkylene group as defined above may be unsubstituted or substituted with one or more substituents as set forth below.

As used herein, the term “cyclic” refers to a ring compound or group comprising at least three carbon atoms and the bonds between pairs of adjacent atoms may all be of the type designated single bonds (involving two electrons), or some of them may be double or triple bonds (with four or six electrons, respectively). Examples of cyclic aliphatic groups can include phenyl, saturated cycloalkyls (e.g., cyclopropyl, cyclobutyl, cyclopentyl, or cyclohexyl), etc.

Monocyclic aromatic hydrocarbon groups are composed of a single aromatic ring, for example benzene, toluene, ethylbenzene, and xylenes. Bicyclic aromatic hydrocarbon groups can contain two benzene rings, such as naphthalene. The aromatic hydrocarbons groups can possess one or more aromatic rings in their structures. Aromatic hydrocarbons are unsaturated hydrocarbons with sigma bonds and pi-electrons that are delocalized between carbon atoms forming a circle. In contrast, aliphatic hydrocarbons lack this delocalization. The aromatic ring according to the present disclosure can be a four-, five-, six-, or seven-membered ring. In some embodiments, the aromatic hydrocarbons have the general chemical formula ChHn. In some embodiments, the aromatic hydrocarbon group contains a benzene ring.

Modifications or derivatives of the compounds disclosed throughout this specification are contemplated as being useful with the methods and compositions of the present disclosure. Derivatives may be prepared and the properties of such derivatives may be assayed for their desired properties by any method known to those of skill in the art. In certain aspects, “derivative” refers to a chemically modified compound that still retains the desired effects of the compound prior to the chemical modification.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

It should also be understood that material compounds will be described in terms of listed elements, e.g., SiN, or SiGe. These compounds include different proportions of the elements within the compound, e.g., SiGe includes SiₓGe₍₁₋ₓ₎ where x is less than or equal to 1, and the like. In addition, other elements can be included in the compound and still function in accordance with the present principles. The compounds with additional elements will be referred to herein as alloys.

Turning now to an overview of technologies that are more specifically relevant to aspects of the present disclosure, area selective deposition (ASD) refers to processes for depositing a film without a lithographic or subtractive process. An example of ASD is atomic layer deposition (ALD), which is a bottom-up technique that is increasingly relied on for its atomic layer-by-layer control of film compositions. This method of film generation relies on efficient chemical reactions at a surface wherein two self-limiting half reactions are alternated to produce conformal thin films even on high-aspect ratio features and three-dimensional structures with an ever-growing materials set. ASD may solve key challenges in wiring nanoscale devices, which are increasingly sensitive to variations in the alignment of multiple lithography steps, to the outside world. ASD is a process that can relax overlay requirements by introducing surface topography to enable self-aligned processes for a commercially relevant implementation.

Furthermore, new device architectures are drawing from a wider variety of nontraditional fabrication methods to produce three-dimensional structures such as resistive random access memory (RRAM) or phase change memory for artificial intelligence (AI) hardware devices. This increases the challenge for traditional fabrication processes and further motivates the development of bottom-up depositions capable of spatial control in three dimensions and on surface topography (e.g., corners, sharp bends, and line-edges).

Several methods have been demonstrated that direct ALD film formation, such as exploiting differences in the reactivity of prepatterned surfaces or utilizing chemical ASD methodologies to either activate regions or prevent deposition. The intrinsic solubility of ALD precursors into polymer domains of nanophase separated block copolymers in the sequential infiltration (SIS) method have also been used to provide etch contrast and enable pattern transfer to a substrate. Organic materials such as conventional resist materials, amorphous carbon, and organic monolayers may be used to inhibit selected regions and direct ALD growth. However, these materials do not fully overcome challenges in scaling and layer formation on patterned surfaces with topography.

Therefore, there is a need for a materials platform that can expand the variety of film compositions and improve the quality of ALD and other ASD techniques. For example, improved formation of material layers that can direct ALD growth may reduce the need to resort to more complex ALD cycles. The utilization of polymeric materials in ASD is attractive given their highly tailorable compositions, where control over the monomeric units provides access to a range of chemical functionalities, such as latent cross-links or supramolecular and dynamic covalent groups. In addition, polymers may provide key parameters to address the challenges of lateral overgrowth onto undesired regions and point defectivity. Polymers may also provide the ability to deposit over surface topographies that often restrict ASD to only a few nanometers. However, there are challenges involved in these techniques.

For example, grafting polymers to a surface has been explored with ligand functionalized polymers but shows poor selectivity in protecting a surface from deposition. Other strategies include polymerization on patterned regions using reactive initiators that bind selectively to substrate regions, followed by formation of a polymer in these regions. However, non-selective reactivity between the initiators and the other regions of the surface often takes place, which can result in loss of contrast, thereby reducing ASD efficiency and introducing defects. An option for overcoming this challenge is prolonged ALD exposure, but this has significant disadvantages such as lack of reliability and large consumption of both ALD precursor and time.

Embodiments of the present disclosure may address these and other challenges involved in ALD and other ASD techniques. In some embodiments, area-selective polymerization on a dielectric surface of a device is enabled by dielectric-selective reactive initiators and metal-selective inhibitors. The polymer formed by the area selective polymerization may inhibit ALD on the dielectric surface. Metal surface passivation via the metal-selective inhibitors can be used to prevent reactivity between the initiators and metal regions of the substrate (e.g., patterned metal features). In some embodiments, the inhibitors are small molecules with metal-binding groups (e.g., reactive substituents with hydroxyl or thiol moieties) and organic ligands (e.g., alkyl chains or cyclic aryl substituents). Metal surface passivation may also improve contrast by preventing polymer film formation on the metal surfaces. In some embodiments, metal passivation can be employed in ASD processes for creating thick (e.g., >2 nm) layers of materials deposited on metal features such as interconnects or barrier materials (e.g., copper or ruthenium features). However, processes for selectively forming material layers of any appropriate thickness may employ the disclosed metal passivation.

ALD can be used to deposit a material on surfaces that are not protected by the patterned polymer. In some embodiments, selectivity may be achieved due to a contrast in ALD inhibition between the inhibitors and the polymer. In other embodiments, the inhibitors may be removed before ALD. In these instances, the inhibitors may be removed before or after the polymerization reaction.

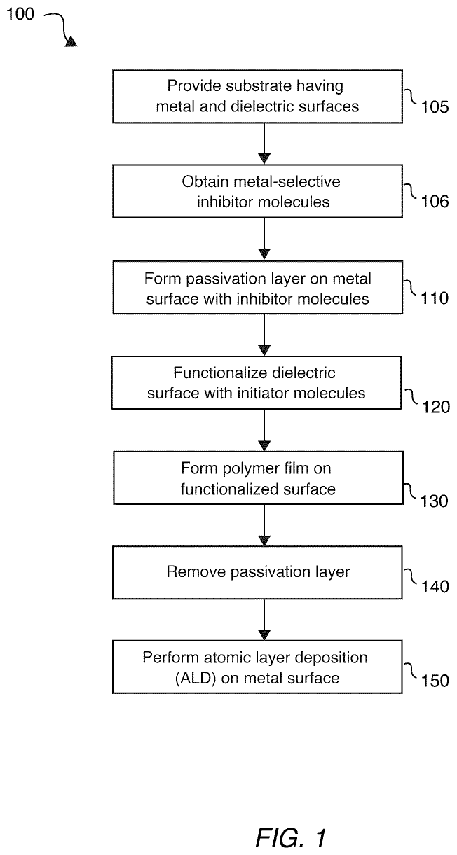

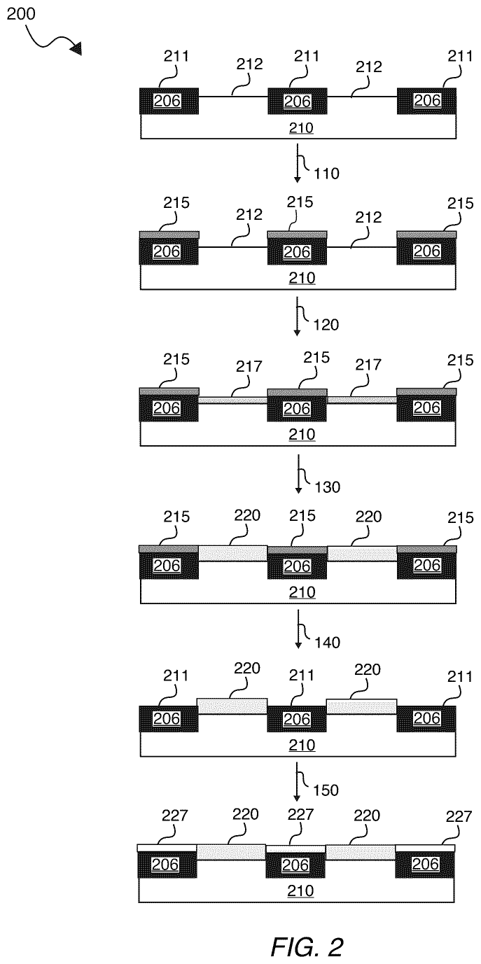

Referring now to the drawings, in which like numerals represent the same or similar elements, FIG. 1 is a flow diagram illustrating a process 100 of ASD, according to some embodiments. Process 100 is discussed with reference to FIG. 2, which is a schematic diagram 200 illustrating ASD on a substrate 210 (side view), according to some embodiments.

A substrate 210 can be provided. This is illustrated at operation 105. The substrate 210 can include a dielectric component, such as a silicon wafer, with coplanar (not shown) or topographical metal feature(s) 206. In some embodiments, the metal features 206 are copper (Cu) or ruthenium (Ru). However, the metal features 206 may include any appropriate metal or metal alloy. Examples of metals that may be used in some embodiments can include cobalt (Co), nickel (Ni), tungsten (W), chromium (Cr), iron (Fe), platinum (Pt), gold (Au), silver (Ag), molybdenum (Mo), gallium (Ga), indium (In), or combinations thereof. Surface(s) of the metal features 206 (metal surfaces 211) may optionally be treated with an oxygen (O₂) or nitrogen (N₂) plasma cleaning process, resulting in metal oxide or metal nitride metal surfaces 211, respectively. Herein, “metal surfaces 211” refers to at least one bare metal surface, metal oxide surface, or metal nitride surface of the metal features 206 unless specified otherwise or clear, based on context, to persons of ordinary skill in the art.

Dielectric surface(s) of the substrate (“dielectric surfaces” 212) can be any portion of the substrate 210 or portion of a material surface formed with a dielectric material. In some embodiments, the dielectric surfaces 212 contain silicon oxide (SiOₓ), silicon nitride (SiₓN_{y}), hydrogenated silicon oxycarbide (SiCOH), or silicon oxycarbonitride (SICNO). Additional examples of dielectric materials/surfaces that may be used in some embodiments can include silicon (Si), silicon oxynitride (SiON), aluminum oxide (AlOₓ), hafnium oxide (HfOₓ), zirconium oxide (ZrO₂), titanium oxide (TiOₓ), titanium nitride (TiN), tantalum oxide (Ta₂O₅), yttrium oxide (Y₂O₃), lanthanum oxide (La₂O₃), aluminum nitride (AlN), magnesium oxide (MgO), calcium fluoride (CaF₂), lithium fluoride (LiF), strontium oxide (SrO), silicon carbide (SiC), barium oxide (BaO), hafnium silicate (HfSiO₄), lanthanum aluminate (LaAlO₃), niobium pentoxide (Nb₂O₅), barium titanate (BaTiO₃), strontium titanate (SrTiO₃), bismuth titanate (Bi₄Ti₃O₁₂), lead zirconium titanate (Pb(Zr,Ti)O₃), calcium copper titanate (CaCu₃Ti₄O₁₂), lithium niobate (LiNbO₃), barium titanate (BaTiO₃), and potassium niobate (KNbO₃).

In some embodiments, operation 105 may also include exposing the substrate 210 to a pretreatment process to polish, coat, dope, etch, reduce, oxidize, hydroxylate, anneal, UV cure, e-beam cure, and/or bake the substrate. As discussed above, the substrate may be treated with a plasma cleaning process. In some embodiments, the plasma may be selected based on the type of dielectric. For example, O₂ or N₂ plasmas may be used for SiO₂ dielectrics. Additionally, for SiCOH or SiCNO, O₂ plasma cleaning may be used to remove adventitious carbon from the dielectric surfaces 212.

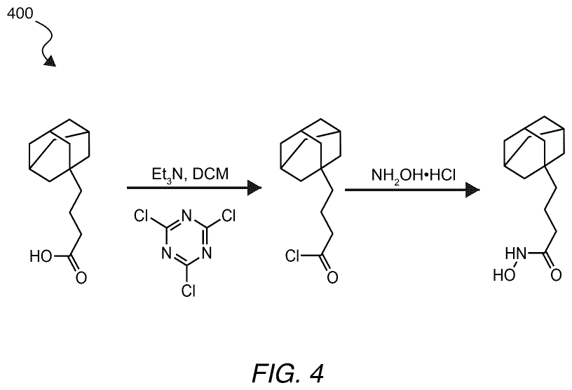

Metal-selective inhibitor molecules (also referred to herein as “inhibitor molecules” or “inhibitors”) can be obtained. This is illustrated at operation 106. Herein, “metal-selective” describes molecules that react preferentially with a metal or metal oxide surface (e.g., relative to dielectrics). This is discussed in greater detail below. Obtaining the inhibitor molecules at operation 106 may include synthetic steps for forming the inhibitors. Examples of synthesis reactions that may be used at operation 106 are discussed below with respect to FIG. 4. In other embodiments, inhibitors may be obtained from another source (e.g., synthesized or isolated by a third party).

For example, the inhibitors may be small molecules with metal-binding groups (e.g., reactive substituents with hydroxyl or thiol moieties) and organic ligands (e.g., alkyl chains or cyclic aryl substituents). In some embodiments, the inhibitors have the following formula (also written as X(CH₂)ₙR):

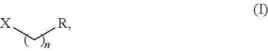

wherein X is a metal-binding group, R is an organic ligand, and n is an integer greater than or equal to zero that represents a number of methylene bridge groups (—CH₂—).

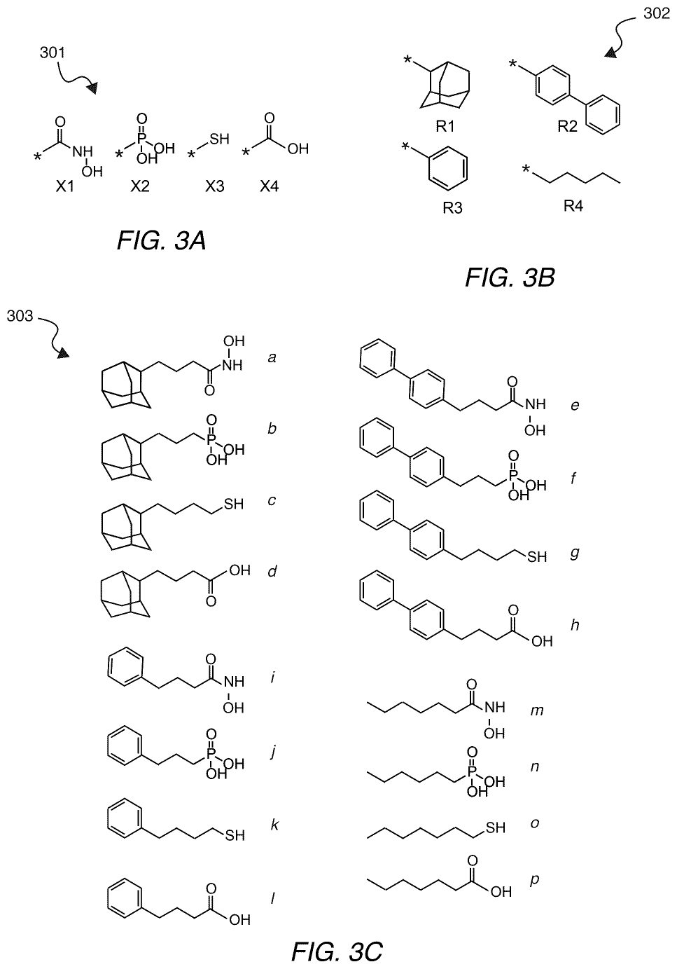

In some embodiments, n=0, 1, 2, 3 or 4, although other numbers of —CH₂— groups are possible. The metal-binding group X may include any appropriate moiety that can direct selective binding onto metal or metal oxide surfaces, such as hydroxyl (—OH) or thiol (—SH) groups. For example, the metal-binding group X may include a hydroxamic acid, phosphonic acid, carboxylic acid, or sulfide substituent in some embodiments. The selectivity of the metal-binding group X may be primarily governed by acid-base interactions, where the acid groups possess organic ligands R that provide a strong driving force for the formation of chemically and thermally stable monolayers. Examples of metal-binding groups that may be selected are discussed below with respect to FIG. 3A, although other selections of X are possible, as will be understood by persons of ordinary skill in the art.

The organic ligand R may be selected from a variety of alkyl (e.g., linear, branched, or cyclic alkyls) and/or aryl groups (e.g., monocyclic, bicyclic, fused-polycyclic, or non-fused polycyclic aryl groups). The organic ligand R may be substantially unreactive with metals, dielectrics, and compounds involved in forming a patterned polymer film (e.g., at operation 130, which is discussed in greater detail below). Further, the organic ligands R may be selected based on their ability to enable efficient packing at surfaces. In some embodiments, the number of —CH₂—groups (n) can be adjusted to enable efficient packing as well. Examples of these selections are discussed below with respect to FIG. 3B, although other selections of R and n are possible, as will be understood by persons of ordinary skill in the art.

FIG. 3A illustrates chemical structure diagrams 301 of example metal-binding groups (X1-X4) for inhibitor molecules, according to some embodiments. The X groups illustrated in FIG. 3A are hydroxamic acid (X1), phosphonic acid (X2), thiol (X3), and carboxylic acid (X4) groups. FIG. 3B illustrates chemical structure diagrams 302 of example organic ligands (R1-R4) for inhibitor molecules, according to some embodiments. The R groups illustrated in FIG. 3B are adamantyl (R1), biphenyl (R2), phenyl (R3), and n-butyl (R4).

The starred bond in each structure shown in FIGS. 3A and 3B represents a bond to a carbon atom of a methylene spacer group when n≥1 in Formula 1 or an atom of a metal-binding group (e.g., carbon (X1 or X4), sulfur (X3), or phosphorus (X2)) when n=0 in Formula 1. For example, an inhibitor with a hydroxamic acid metal-binding group (X1), an adamantyl organic ligand (R1), and three —CH₂— methylene spacers (n=3) can be represented by: X¹(CH₂)₃R¹, and an inhibitor with a hydroxamic acid metal-binding group (X1) bound directly to a phenyl organic ligand (R3) can be represented by: X¹R³. Various combinations of X and R can be used, such as those shown in FIG. 3C.

FIG. 3C illustrates chemical structure diagrams 303 of metal-binding inhibitor molecules (a-p), according to some embodiments. Inhibitor molecules obtained at operation 106 may include at least one of the illustrated compounds a-p:X¹(CH₂)₃R¹ (a), X²(CH₂)₃R¹ (b), X³(CH₂)₄R¹ (c), X⁴(CH₂)₃R¹ (d), X¹(CH₂)₃R² (e), X²(CH₂)₃R² (f), X³(CH₂)₄R² (g), X⁴(CH₂)₃R² (h), X¹(CH₂)₃R³ (i), X²(CH₂)₃R³ (j), X³(CH₂)₄R³ (k), X⁴(CH₂)₂R³ (l), X¹(CH₂)₃R⁴ (m), X²(CH₂)₃R⁴ (n), X³(CH₂)₄R⁴ (o), and X⁴(CH₂)₃R⁴ (p). Inhibitors that may be used in further embodiments (not shown in FIG. 3C) may include X¹R³ (benzohydroxamic acid), X²R⁵ (propylphosphonic acid), X²R³ (phenylphosphonic acid), and X³R³ (thiophenol). However, as discussed above, a variety of inhibitors represented by Formula I may be used.

FIG. 4 is a chemical reaction diagram illustrating a process 400 of synthesizing a metal-binding inhibitor molecule (e.g., at operation 106), according to some embodiments. In process 400, 4-(1-adamantane) butanoic acid can be reacted with cyanuric chloride (2,4,6-trichloro-1,3,5-triazine) in a triethylamine/dichloromethane (Et₃N/DCM) solution. The product of this reaction can be reacted with hydroxylamine hydrochloride (NH₂OH•HCl), resulting in the inhibitor X¹(CH₂)₃R¹ (a). Substantially similar reaction conditions may be used to prepare other inhibitors from appropriate precursors, as will be understood by persons of ordinary skill in the art.

With the inhibitors obtained at operation 106, process 100 can proceed to operations 110-150, which are illustrated in FIGS. 1 and 2. At operation 110, the metal surfaces 211 can be passivated by forming a layer of the metal-selective inhibitor molecules (“passivation layer” 215). For example, the substrate 210 can be exposed to a solution of inhibitors dissolved in, e.g., methyl isobutyl carbinol (MIBC, 4-methyl-2-pentanol), propylene glycol methyl ether acetate (PGMEA, 1-methoxy-2-propanol acetate) and/or propylene glycol methyl ether (PGME, 1-methoxy-2-propanol). In some embodiments, the concentration of inhibitors in the solution is between about 0.1-1.0 wt. %. The substrate 210 may be exposed to the inhibitor solution for, e.g., 1-30 minutes, followed by rinsing with solvent (e.g., MIBC, PGMEA, and/or PGME) to remove excess materials.

For example, a silicon substrate (e.g., substrate 210) with patterned copper features (e.g., metal features 206) can be cleaned with an O₂ plasma, forming a layer of copper oxide on the surfaces of the copper features (e.g., metal surfaces 211). The cleaned surfaces (including, at least, the oxidized copper surfaces), can then be coated with the initiator solution at room temperature. In other embodiments, the metal surfaces 211 may be bare metal. For example, the surfaces of the copper features may be bare copper that has been cleaned with acetic acid prior to coating with the initiator solution. Selective binding of the inhibitors to the copper surfaces can result in a metal-passivating layer of inhibitor molecules (e.g., passivation layer 215).

The dielectric surfaces 212 can then be functionalized with a layer of surface-bound initiator molecules (“initiator layer” 217). This is illustrated at operation 120. Portions of the substrate 210 including, at least, the dielectric surfaces 212 can be exposed to dielectric-selective initiator molecules (also referred to herein as “initiator molecules” or “initiators”). The initiator molecules have reactive groups that can bind to the dielectric surfaces 212 to form the initiator layer 217. The initiator molecules can be prevented from binding to the metal surfaces 211, at least in part, by the passivation layer 215. Additionally, the reactive groups may include moieties with greater selectively for binding to dielectrics than metals, such as silanes.

The initiator molecules also have substituents that can enable subsequent polymer growth at the dielectric surface 212 (see below at operation 130). Examples of initiator molecules may include vinyl-alkyl-chlorosilanes, norbornene-alkyl-chlorosilanes (e.g., [(5-bicyclo [2.2.1]hept-2-enyl)ethyl]-methyldichlorosilane), APTES ((3-aminopropyl)triethoxysilane), etc. Any appropriate techniques known to persons of ordinary skill in the art may be used to apply the initiators. For example, a toluene, hexane, and/or heptane solution of the initiators may be applied to the surfaces of the substrate 210 (e.g., by immersion in the solution) followed by washing with the same solvent or solvent mixture.

A polymerization reaction with the surface-bound initiator molecules can form a surface-bound polymer film 220. This is illustrated at operation 130. The surface-bound polymer film 220 may be a polymer that can inhibit ALD, such as a polyolefin. In some embodiments, the surface-bound polymer film 220 can be formed via ring-opening metathesis polymerization (ROMP) at the initiator layer 217. In these instances, a catalyst can be used to activate the surface-bound initiators. For example, the catalyst may be a high initiation rate ruthenium-based catalyst, such as Grubbs generation III ([1,3-bis(2,4,6-trimethylphenyl)-2-imidazolidinylidene]dichloro(benzylidene)bis(3-bromopyridine) ruthenium (II)). In other embodiments, the ROMP reaction may employ another catalyst, such as Hoveyda-Grubbs generation I (dichloro(o-isopropoxyphenylmethylene) (tricyclohexylphosphine) ruthenium (II)) or Hoveyda-Grubbs generation II (dichloro [1,3-bis(2,4,6-trimethylphenyl)-2-imidazolidinylidene](2-isopropoxyphenylmethylene) ruthenium (II)).

Monomers can be reacted with the activated initiators to grow the polymer film 220. For example, the monomers may acrylate or olefin monomers or any other monomers appropriate for the polymer film 220 to be grown. In some embodiments, the ROMP reaction is carried out with a norbornene-alkyl-chlorosilane initiator, Grubbs generation III catalyst, and olefin monomer. Olefin monomers that can be used in these and other embodiments may include norbornene, octadiene, norbornadiene, dicyclopentadiene, cis-cyclooctene, etc.

The monomers may be applied using chemical vapor deposition (CVD). For example, the functionalized dielectric surface 212 can be exposed to the monomer at atmospheric pressure. In some embodiments, ROMP begins within several seconds of monomer exposure. Monomer exposure times can range from, e.g., about 30 minutes to 18 hours, but any appropriate exposure time may be used. The exposure time may be adjusted based on the desired thickness of polymer film 220. The ultimate thickness of the polymer film 220 can depend on ring-strain of the monomer. For example, highly ring-strained monomers (e.g., norbornene) can result in thicker films 220 (e.g., up to about 850 nm) than lower ring-strained monomers such as cis-cyclooctene.

The polymer chain growth can be terminated by removing/deactivating the catalyst. For example, after the monomer exposure is complete, the polymer film 220 can be treated with a solution of ethyl vinyl ether (e.g., 10% ethyl vinyl ether in dichloromethane), which can irreversibly bind with catalysts such as Grubbs generation III to cause their removal from the polymer.

In some embodiments, the passivation layer 215 can be removed from the metal surfaces 211 after the polymer film 220 is formed. This is illustrated at operation 140 (see below). In other embodiments (not shown), operation 140 may be carried out after functionalizing the dielectric surfaces 212 in operation 120, but before the polymerization at operation 130. In further embodiments, operation 140 may be omitted from process 100. For example, if the type of polymer film 220 inhibits ALD significantly more than the passivation layer 215, operation 140 may be unnecessary.

Various methods may be used to remove the passivation layer 215 at operation 140. These may include, e.g., solution-phase liftoff techniques or heating at back end of line (BEOL) compatible temperatures. For example, the passivated surfaces may be exposed to an aqueous solution of 10-50 wt. % acetic acid at a temperature range of about 25-45° C. for ˜2-10 min. In another example, the passivated surfaces may be exposed to an aqueous solution of 1-5 wt. % metal salt (e.g., a salt of Zn²⁺) within a temperature range of about 25-50° C. for a period of ˜5-20 min. In embodiments where a thiolate-based inhibitor is used, the initiator layer 217 may optionally be removed by heating the substrate for ˜5-20 min. in an ALD tool at about 250-350° C.

ALD can be used to form material layers on surface regions of the substrate 210 not protected by the polymer film 220 (e.g., metal surfaces 211 from which, in some embodiments, the passivation layer 215 has been removed). This is illustrated at operation 150. For example, ALD can be used to form a metal oxide film 227 over the patterned metal features 206. Any appropriate precursors for forming the metal oxide film 227 can be deposited at operation 150. For example, formation of TiO₂ films may use tetrakis(dimethylamido) titanium (IV) as a precursor, formation of HfO₂ films may use tetrakis(dimethylamido) hafnium (IV), formation of ZnO films may use diethylzinc, formation of Al₂O₃ films may use trimethylaluminum, etc.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A process of area selective deposition (ASD), comprising:
forming a passivation layer on a metal surface of a substrate, wherein the forming comprises binding metal-selective inhibitor molecules to the metal surface; and
forming a surface-bound polymer film on a dielectric surface of the substrate.

2. The process of claim 1, further comprising performing atomic layer deposition (ALD) on the metal surface.

3. The process of claim 2, further comprising removing the passivation layer prior to performing the ALD.

4. The process of claim 1, wherein the metal-selective inhibitor molecules have the following structure: 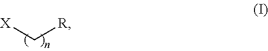
wherein X is a metal-binding group, R is an organic ligand, and n is an integer greater than or equal to zero.

5. The process of claim 4, wherein X is selected from the group consisting of hydroxamic acid, phosphonic acid, thiol, and carboxylic acid substituents.

6. The process of claim 4, wherein n=3.

7. The process of claim 4, wherein R is selected from the group consisting of an alkyl chain, adamantyl, and phenyl.

8. The process of claim 1, further comprising treating the substrate with oxygen plasma prior to the passivating.

9. The process of claim 1, wherein the forming the surface-bound polymer film comprises functionalizing the dielectric surface with surface-bound initiator molecules.

10. A process of atomic layer deposition (ALD), comprising:
forming a passivation layer on a metal surface of a substrate, wherein the forming comprises binding metal-selective inhibitor molecules to the metal surface; and
forming a surface-bound polymer film on a dielectric surface of the substrate.

11. The process of claim 10, wherein the metal-selective inhibitor molecules have the following structure: 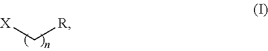
wherein X is a metal-binding group, R is an organic ligand, and n is an integer greater than or equal to zero.

12. The process of claim 11, wherein X is selected from the group consisting of hydroxamic acid, phosphonic acid, thiol, and carboxylic acid substituents.

13. The process of claim 11, wherein n=3.

14. The process of claim 11, wherein R is selected from the group consisting of an alkyl chain, adamantyl, and phenyl.

15. The process of claim 10, wherein the forming the surface-bound polymer film comprises functionalizing the dielectric surface with surface-bound initiator molecules.

16. A process of device fabrication, comprising:
forming a passivation layer on a metal surface of a substrate, wherein the forming comprises binding metal-selective inhibitor molecules to the metal surface; and
forming a surface-bound polymer film on a dielectric surface of the substrate.

17. The process of claim 16, wherein the metal-selective inhibitor molecules have the following structure: 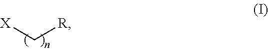
wherein X is a metal-binding group, R is an organic ligand, and n is an integer greater than or equal to zero.

18. The process of claim 16, wherein the forming the surface-bound polymer film comprises functionalizing the dielectric surface with surface-bound initiator molecules.

19. The process of claim 16, further comprising:
removing the passivation layer; and
forming a metal oxide film on the metal surface without the passivation layer.

20. A device formed in a process comprising:
forming a passivation layer on a metal surface of a substrate, wherein the forming comprises binding metal-selective inhibitor molecules to the metal surface; and
forming a surface-bound polymer film on a dielectric surface of the substrate.

21. The device of claim 20, wherein the metal-selective inhibitor molecules have the following structure: 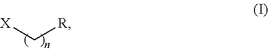
wherein X is a metal-binding group, R is an organic ligand, and n is an integer greater than or equal to zero.

22. The device of claim 21, wherein X is selected from the group consisting of hydroxamic acid, phosphonic acid, thiol, and carboxylic acid.

23. The device of claim 21, wherein R is selected from the group consisting of an alkyl chain, adamantyl, and phenyl.

24. The device of claim 20, wherein the forming the surface-bound polymer film comprises functionalizing the dielectric surface with surface-bound initiator molecules.

25. A composition for area selective deposition (ASD), comprising a metal-selective inhibitor molecule have the following structure: 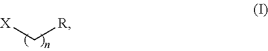
wherein X is a metal-binding group, R is an organic ligand, and n is an integer greater than or equal to zero.
